(19) United States
(12) Patent Application Publication
(10) Pub. No.: US 2005/0269602 A1
(43) Pub. Date: Dec. 8, 2005

(54) Semiconductor device and method of manufacturing the same

(75) Inventors: Yoshiki Maruyama, Tokyo (JP); Tatsunori Kaneoka, Tokyo (JP); Toshiya Uenishi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/144,816

(22) Filed: Jun. 6, 2005

(30) Foreign Application Priority Data
Jun. 7, 2004 (JP) 2004-168098
May 17, 2005 (JP) 2005-143533

(51) Int. Cl. H01L 29/78; H01L 21/76

(52) U.S. Cl. 257/288; 438/425; 438/435; 257/506

(57) ABSTRACT

The inner wall of a trench formed in an element isolation region on a silicon substrate is oxidized to form an inner wall oxide film. The inner wall oxide film is subjected to two nitridation steps including thermal nitridation and radical nitridation. A first nitride layer is formed by the thermal nitridation near the interface between the inner wall oxide film and the silicon substrate. A second nitride layer is formed on a surface of the inner wall oxide film by the radical nitridation. In the thermal nitridation, the amount of nitrogen to be introduced is limited such that a semiconductor element to be formed in an active region is not degraded in reliability.

### BACKGROUND OF THE INVENTION

1. Field of the Invention

The present invention relates to a semiconductor device and a method of manufacturing the same, and more particularly, to an isolation structure between semiconductor elements.

2. Description of the Background Art

Trench isolation such as STI (Shallow Trench Isolation) is widely known as an element isolation structure for isolating elements of a semiconductor device from each other. Conventional trench isolation has generally been formed by the following steps: (i) selectively etching an element isolation region on a silicon substrate to form a trench; (ii) oxidizing the surface of the silicon substrate to form an inner wall oxide film on the inner wall of the trench; and (iii) filling the trench with an oxide film to form an isolation oxide film.

In the process of manufacturing a semiconductor device, a step involving thermal oxidization of a silicon substrate is generally conducted after forming trench isolation. For instance, in the process of manufacturing a semiconductor device having a MOS (Metal Oxide Semiconductor) transistor, the main surface of a silicon substrate is thermally oxidized after forming trench isolation in the silicon substrate, to form a gate oxide film. In the case where oxidization of the trench inner wall further progresses in the thermal oxidization after forming the trench isolation, the volume of that portion increases, causing compressive stress to be produced around the trench isolation. As a result, crystal defect is produced in an active region (element forming region) defined by the trench isolation, which in turn increases the leakage current of a semiconductor device formed in that region. The above-mentioned step (ii) is to previously oxidize the trench inner wall before forming the isolation oxide film to overcome such problem.

There is a technique for introducing nitrogen into the inner wall oxide film by conducting thermal nitridation using NO gas, NH₃ gas or the like (that is, for turning part of the inner wall oxide film into an oxynitride film). In the case where nitrogen is introduced into the inner wall oxide film, an oxidizer passed through the isolation oxide film is prevented from passing through the inner wall oxide film to reach the silicon substrate in the thermal oxidization after forming trench isolation; that is, the trench inner wall is prevented from being further oxidized after forming the trench isolation, which prevents an increase in volume. These effects are improved as the amount of nitrogen introduced into the inner wall oxide film increases.

In the case of thermally nitriding the inner wall oxide film, nitrogen is mainly introduced into a relatively deep position such as the vicinity of the interface between the inner wall oxide film and silicon substrate. Thus, nitrogen is introduced deep to reach the surface of the silicon substrate which underlies the inner wall oxide film. The above-described effects are improved as the amount of nitrogen introduced into the inner wall oxide film increases; however, introduction of a great amount of nitrogen into the surface of the silicon substrate interferes with the progress of oxidization when oxidizing the surface of the silicon substrate for forming the gate oxide film, for example, which raises a problem (called “thinning”) in that a desired film thickness cannot be obtained at the edges of the gate oxide film in the active region (areas C shown in FIGS. 1B and 2 which will be described later). Another problem also arises in that a nitrogen-induced level occurs at the interface between the silicon substrate and gate oxide film. These problems cause the gate oxide film to be degraded in breakdown voltage and Qbd (charge to breakdown) as well as inducing a kink phenomenon, which result in reduced reliability of the semiconductor device.

There is still another technique proposed for forming an oxynitride film layer only on the surface of an inner wall oxide film by radical nitridation in order to prevent nitrogen from being introduced into the surface of a silicon substrate along with the nitridation of the inner wall oxide film (e.g., Japanese Patent Application Laid-Open No. 2004-47599).

As described above, the occurrence of crystal defect resulting from oxidization of the trench inner wall is further prevented as the amount of nitrogen introduced into the inner wall oxide film increases, allowing the leakage current of a semiconductor element to be controlled. These effects are particularly important in recent years as finer design rules and lower power consumption of semiconductor devices are being desired. However, nitrogen introduced into the silicon substrate may cause a semiconductor element to be degraded in reliability. That is, with respect to the introduction of nitrogen into the inner wall oxide film, the prevention of occurrence of crystal defect and the improvement in reliability disagree with each other. Further, the technique disclosed in the above JP2004-47599 does not fully achieve the effect of preventing an oxidizer from reaching the substrate in the case where oxidization after forming an isolation oxide film is conducted to a great degree.

### SUMMARY OF THE INVENTION

An object of the present invention is to introduce a great amount of nitrogen into the inner wall of a trench in a semiconductor device having a trench isolation structure while preventing the semiconductor device from being degraded in reliability.

According to a first aspect of the present invention, a method of manufacturing a semiconductor device comprises the following steps (a) through (d). The step (a) is to form a trench in a semiconductor substrate. The step (b) is to oxidize an inner wall of the trench to form an inner wall oxide film. The step (c) is to introduce nitrogen into the inner wall oxide film. The step (d) is to fill the trench with an isolation insulation film. The step (c) includes the following steps (c-1) and (c-2). The step (c-1) is to introduce nitrogen into a relatively deep position in the inner wall oxide film. The step (c-2) is to introduce nitrogen into a relatively shallow position in the inner wall oxide film.

According to a second aspect of the invention, a method of manufacturing a semiconductor device comprises the following steps (a) through (e). The step (a) is to form a trench in a semiconductor substrate. The step (b) is to introduce nitrogen into an inner wall of the trench. The step (c) is to oxidize the inner wall of the trench with nitrogen introduced therein to form an inner wall oxide film. The step (d) is to introduce nitrogen into the inner wall oxide film. The step (e) is to fill the trench with an isolation insulation film.

According to a third aspect of the invention, a semiconductor device comprises a trench formed in a semiconductor substrate, an inner wall oxide film formed on an inner wall of the trench and an isolation insulation film which fills the trench. Nitrogen is contained at least partially in the inner wall oxide film. The distribution of concentration of the nitrogen along the thickness of the inner wall oxide film presents two peaks.

According to a fourth aspect of the invention, a semiconductor device comprises a trench formed in a semiconductor substrate, an inner wall oxide film formed on an inner wall of the trench and an isolation insulation film which fills the trench. Nitrogen is contained throughout the inner wall oxide film. The distribution of concentration of the nitrogen in the inner wall oxide film presents a peak in the vicinity of a surface of the inner wall oxide film.

According to a fifth aspect of the invention, a semiconductor device comprises a trench formed in a semiconductor substrate, a first nitride layer formed along an inner wall of the trench, a second nitride layer formed in an inner side of the trench than the first nitride layer and an isolation insulation film which fills the trench.

Nitrogen can be introduced into the inner wall oxide film in a greater amount than in the conventional case. Therefore, oxidization of the inner wall of a trench is prevented from progressing in thermal oxidization (e.g., formation of a gate oxide film on a semiconductor substrate) after forming an isolation oxide film, preventing an increase in volume, which in turn prevents crystal defect from occurring in an active region where a semiconductor element is to be formed.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are sectional views showing the structure of a semiconductor device according to a first preferred embodiment of the present invention,

FIG. 2 is a top view showing the structure of the semiconductor device according to the first preferred embodiment;

FIGS. 3 to 6 are process drawings showing a method of manufacturing the semiconductor device according to the first preferred embodiment;

FIG. 7 is a graph showing the effects of the invention;

FIG. 8 is a sectional view showing the structure of a semiconductor device according to a third preferred embodiment of the invention; and

FIGS. 9 and 10 are process drawings showing a method of manufacturing the semiconductor device according to the third preferred embodiment.

### DESCRIPTION OF THE PREFERRED EMBODIMENTS

### First Preferred Embodiment

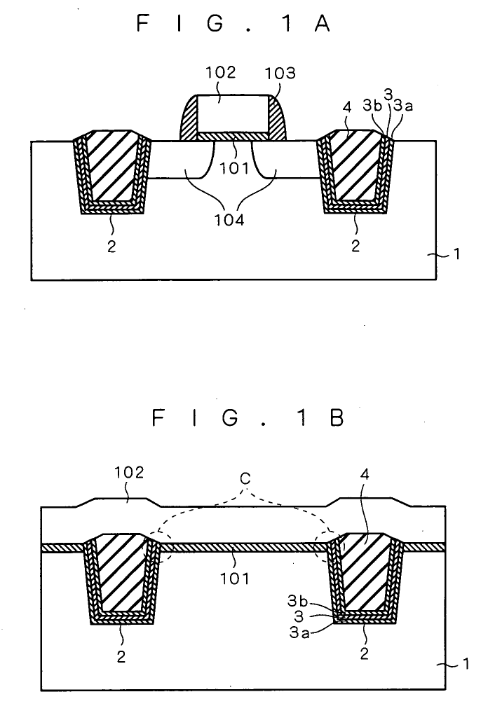

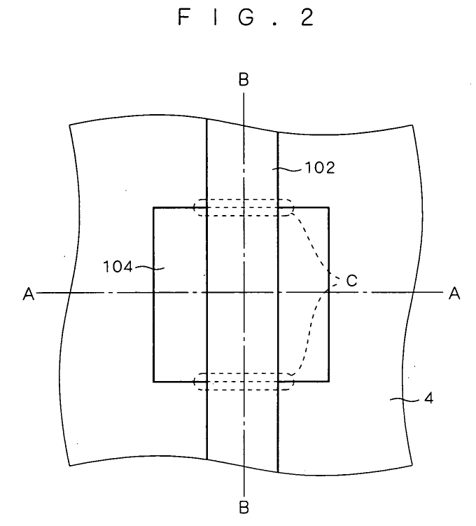

FIGS. 1A, 1B and 2 show the structure of a semiconductor device according to a first preferred embodiment of the present invention. FIGS. 1A and 1B are both sectional views of a MOS transistor, and FIG. 2 is a top view thereof. FIG. 1A corresponds to a section taken along the line A-A (i.e., along the gate length) shown in FIG. 2, and FIG. 1B corresponds to a section taken along the line B-B (i.e., along the gate width). In these drawings, the same elements are indicated by the same reference characters.

As shown in FIGS. 1A and 1B, formed in a silicon substrate 1 is a MOS transistor made up of a gate oxide film 101, a gate electrode 102, a sidewall 103 and source/drain regions 104. An active region (element forming region) where the MOS transistor is formed is defined by a trench isolation including a trench 2 formed in an element isolation region and an isolation oxide film 4 which fills the trench 2.

An inner wall oxide film 3 is formed on the inner wall of the trench 2. Nitrogen is introduced into the vicinity of the interface between the inner wall oxide film 3 and silicon substrate 1 and the interface between the inner wall oxide film 3 and isolation oxide film 4, to form a first nitride layer 3a and a second nitride layer 3b, respectively. In other words, the distribution of nitrogen concentration along the thickness of the inner wall oxide film 3 presents a first peak in a relatively deep position, that is, in the vicinity of the interface with the silicon substrate 1 and a second peak in a relatively shallow position, that is, in the vicinity of the interface with the isolation oxide film 4. It is preferable that the first peak should be lower than the second peak (which will be discussed later in detail). Throughout this specification, the “inner wall oxide film” shall include a nitrogen-containing layer in the inner wall oxide film.

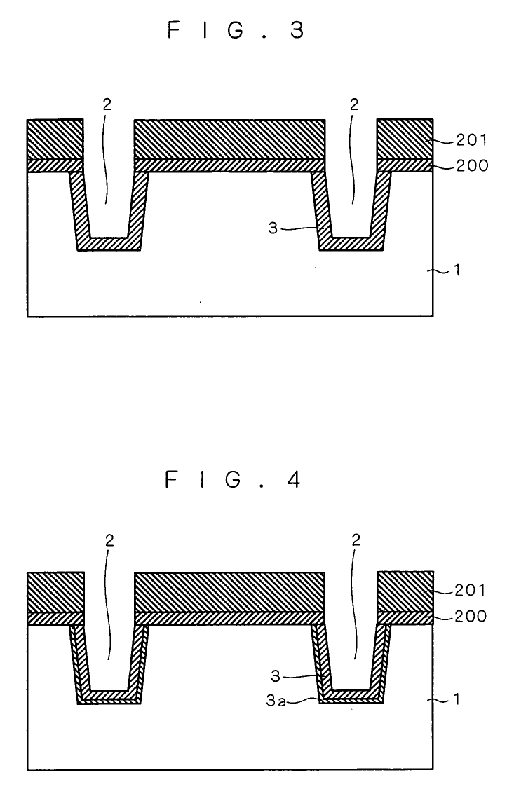

FIGS. 3 to 6 are process drawings showing a method of manufacturing the semiconductor device shown in FIGS. 1A and 1B. The method of manufacturing the semiconductor device according to the present embodiment will now be described in reference to these drawings.

First, similarly to the conventional steps of forming trench isolation, a silicon oxide film 200 and a silicon nitride film 201 are successively formed on the silicon substrate 1, and are patterned to form an opening above the element isolation region where the isolation oxide film 4 is to be formed. The trench 2 is formed in the element isolation region on the silicon substrate 1 by etching using the patterned silicon oxide film 200 and silicon nitride film 201 as a mask, and then, the surface of the silicon substrate 1 including the inner wall of the trench 2 is oxidized to form the inner wall oxide film 3 (FIG. 3).

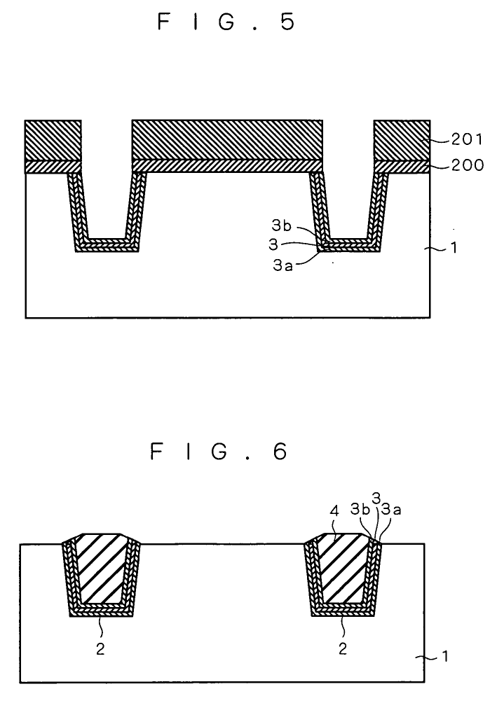

Thereafter, the inner wall oxide film 3 is thermally nitrided using a nitrogen-containing gas. As a gas available for the thermal nitridation, NO gas, N₂O gas, NH₃ gas and the like are known. Particularly in the case of nitriding an oxide film on a silicon substrate using NO gas or N₂O gas, nitridation mainly progresses at the interface between the oxide film and silicon substrate. In the present embodiment, the first nitride layer 3a is formed in the vicinity of the interface between the inner wall oxide film 3 and silicon substrate 1 using NO gas, N₂O gas or the like (FIG. 4). That is, through this step, the first peak of nitrogen concentration occurs in a relatively deep position in the inner wall oxide film 3.

However, the introduction of a great amount of nitrogen into the vicinity of the interface between the inner wall oxide film 3 and isolation oxide film 4 arises the problem of thinning of the gate oxide film 101 at the edges of the active region (areas C shown in FIGS. 1B and 2) and the problem of occurrence of a nitrogen-induced level at the interface between the gate oxide film 101 and silicon substrate 1, as described above. Therefore, the amount of nitrogen introduced by the thermal nitridation needs to be limited such that these problems do not interfere with the characteristics of the MOS transistor.

Subsequently, the inner wall oxide film 3 is further nitrided by radical nitridation using radical species of nitrogen. The use of plasma is known as a method of producing radical species of nitrogen. Radical species immediately create chemical bonds with other atoms or molecules, and thus have a high reactivity at the surface. The second nitride layer 3b is thereby formed on the surface of the inner wall oxide film 3 (FIG. 5). That is, through this step, the second peak of nitrogen concentration occurs in a relatively shallow position in the inner wall oxide film 3.

In the radical nitridation, it is not necessary to limit the amount of nitrogen to be introduced since the aforementioned problems of thinning and occurrence of a nitrogen-induced level do not arise even when a great amount of nitrogen is introduced into the vicinity of the surface of the inner wall oxide film 3 (i.e., the interface between the inner wall oxide film 3 and isolation oxide film 4 shown in FIGS. 1A and 1B).

As described, the step of introducing nitrogen into the inner wall oxide film 3 includes a first step of introducing nitrogen into a relatively deep position in the inner wall oxide film 3 and a second step of introducing nitrogen into a shallower position than in the first step. The amount of nitrogen introduced into the inner wall oxide film 3 in the first step is smaller than in the second step. As a result, in the distribution of nitrogen concentration in the inner wall oxide film 3, the first peak presented in a relatively deep position is lower than the second peak presented in a shallower position than the first peak.

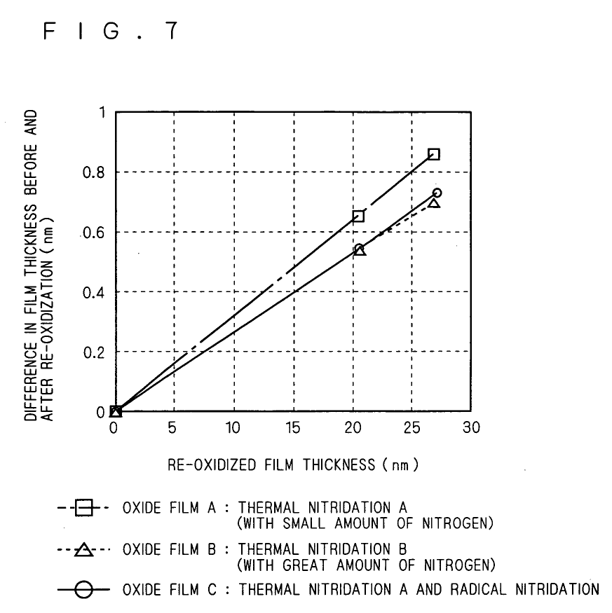

Thereafter, a silicon oxide film is deposited over the entire surface of the silicon substrate 1 including the inside of the trench 2, and excess deposit outside the trench 2 is removed by etching or CMP process, so that the isolation oxide film 4 is formed to fill the trench 2. Further, the silicon nitride film 201 and silicon oxide film 200 are removed to uncover the main surface of the silicon substrate 1 (FIG. 6).

Then, the upper surface of the uncovered part of the silicon substrate 1 is thermally oxidized to form a silicon oxide film, and an electrode material such as polysilicon is deposited thereon. The silicon oxide film and electrode material are patterned to form the gate oxide film 101 and gate electrode 102. Further, the sidewall 103 is formed on the side face of the gate electrode 102, and the source/drain regions 104 are formed in the silicon substrate 1 by ion implantation. The MOS transistor is thereby formed in the active region on the silicon substrate 1, as shown in FIGS. 1A and 1B.

In the present embodiment, the step of introducing nitrogen into the inner wall oxide film 3 includes the first step of introducing nitrogen into a relatively deep position in the inner wall oxide film 3 and the second step of introducing nitrogen into a shallower position than in the first step. This allows nitrogen to be introduced into the inner wall oxide film 3 in a greater amount than in the conventional case. Accordingly, an oxidizer is prevented from reaching the substrate in the thermal oxidization thereafter (for forming the gate oxide film 101), which in turn prevents oxidization of the inner wall of the trench 2 from progressing. Therefore, an increase in volume is prevented, which in turn prevents crystal defect from occurring in the active region.

Further, since the amount of nitrogen introduced into the vicinity of the interface between the inner wall oxide film 3 and isolation oxide film 4 is limited to a small amount in the first step, nitrogen remains little at the edges of the active region on the upper surface of the silicon substrate 1 when forming the gate oxide film 101. Therefore, the problem of thinning at the edges of the gate oxide film 101 in the active region (areas C shown in FIGS. 1B and 2) and the problem of occurrence of a nitrogen-induced level at the interface between the gate oxide film 101 and silicon substrate 1 can be solved. In the second step, it is not required to put a limit on the amount of nitrogen introduced into the surface of the inner wall oxide film 3. As the amount of nitrogen increases, the above-mentioned effects can be obtained more securely. In other words, the present embodiment can prevent crystal defect from occurring in the active region by introducing a great amount of nitrogen into the inner wall oxide film 3 while preventing nitrogen from being introduced excessively into the vicinity of the interface between the inner wall oxide film 3 and isolation oxide film 4 to maintain the reliability of the semiconductor device.

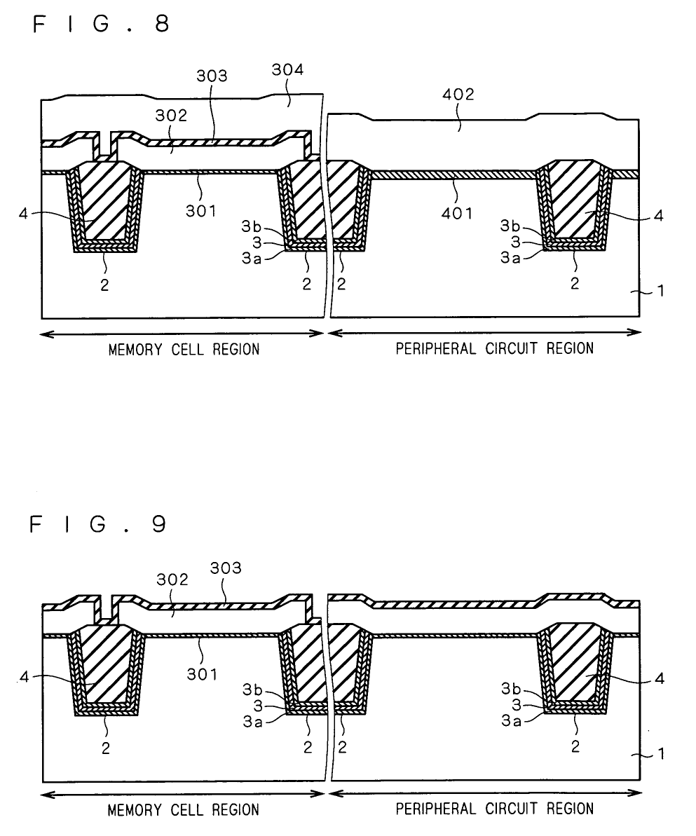

FIG. 7 is a graph plotting the results of experiment for describing the effects achieved by the present invention. In the experiment, an oxide film was formed on the surface of a sample silicon substrate, and a predetermined amount of nitrogen was introduced into the oxide film. Then, the oxide film was thermally re-oxidized, and variations in thickness of the oxide film before and after the re-oxidization were monitored. The thickness of oxide film was measured by an optical film-thickness measuring instrument. The horizontal axis of the graph indicates the thickness of oxide film (re-oxidized film thickness) in which the silicon substrate serving as a monitor wafer was oxidized in the re-oxidization, and the vertical axis indicates the difference in thickness of oxide film before and after the re-oxidization. The experiment was conducted on an oxide film A subjected only to thermal nitridation A of introducing a relatively small amount of nitrogen, an oxide film B subjected only to thermal nitridation B of introducing a relatively great amount of nitrogen and an oxide film C subjected to the radical nitridation in addition to the thermal nitridation A.

As is apparent from the graph of FIG. 7, the increase in thickness of the oxide film B caused by the re-oxidization is kept smaller than in the oxide film A. Besides, nitrogen is introduced into the interface between the oxide film C and silicon substrate 1 only in a similar amount as in the case of the oxide film A (smaller than in the case of the oxide film B) since a nitride layer is formed on the surface of the oxide film by the radical oxidization, however, similar results obtained in the case of the oxide film B were obtained in the case of the oxide film C. That is, it is apparent that, even when a limit is imposed on the amount of nitrogen to be introduced into the interface between the oxide film and silicon substrate, the effect of suppressing an increase in volume of oxide film in the re-oxidization is improved by introducing nitrogen also into the surface of the oxide film as in the invention of the present application. It has been confirmed that the above-described effects are obtained in the present invention.

In the present embodiment, the first step is conducted before the second step in the process of introducing nitrogen into the inner wall oxide film 3, however, either of the first and second steps may be conducted first. Similar effects can be obtained whichever comes first.

In the first step, the peak (first peak) of nitrogen concentration is presented in the vicinity of the interface between the inner wall oxide film 3 and silicon substrate 1 by conducting the thermal nitridation using NO gas, N₂O gas or the like, however, the peak does not always need to be presented in the vicinity of the interface between the inner wall oxide film 3 and silicon substrate 1. For instance, thermal nitridation using NH₃ gas may be conducted as the first step. In the case of using NH₃ gas, nitridation occurs not only in the vicinity of the interface between the inner wall oxide film 3 and silicon substrate 1 but also inside the inner wall oxide film 3, which may cause the peak of nitrogen concentration to appear near the center of the inner wall oxide film 3.

In the second step, the peak (second peak) is presented in the surface of the inner wall oxide film 3 by conducting the radical nitridation, however, the peak does not always need to be presented in the surface of the inner wall oxide film 3, but only needs to be positioned in a shallower position than in the first step.

In other words, the effects of the present invention can be achieved unless at least one of the peaks of nitrogen concentration respectively formed in the first and second steps overlaps the interface between the inner wall oxide film 3 and silicon substrate 1. Further, the method of introducing nitrogen used in the first and second steps are not limited to the thermal nitridation and radial nitridation, respectively. For instance, a method of using ion species may be employed.

### Second Preferred Embodiment

In the method of manufacturing a semiconductor device according to the present invention, the step of introducing nitrogen into the inner wall of the trench 2 on which the inner wall oxide film 3 is formed is conducted twice. For instance, in the first preferred embodiment, the inner wall oxide film 3 is first formed on the inner wall of the trench 2, and then, the two steps of introducing nitrogen (the first step of introducing nitrogen into a relatively deep position and the second step of introducing nitrogen into a relatively shallow position) are conducted.

According to the present invention, however, the two steps of introducing nitrogen do not always need to be conducted after forming the inner wall oxide film 3. In a second preferred embodiment, one of the first and second steps is conducted before forming the inner wall oxide film 3.

More specifically, in the method of manufacturing a semiconductor device according to the present embodiment, a first step of introducing nitrogen into the inner wall of the trench 2 (before forming the inner wall oxide film 3 thereon) to form a nitrogen-containing layer. Next, a step of oxidizing the inner wall of the trench 2 with nitrogen introduced therein to form the inner wall oxide film 3. Then, a second step of introducing nitrogen again into the inner wall of the trench 2 with the inner wall oxide film 3 formed thereon is conducted.

In the case where the first introduction step, the step of forming the inner wall oxide film 3 and the second introduction step are conducted in the order described, nitrogen introduced into the inner wall of the trench 2 in the first step diffuses throughout the inner wall oxide film 3 in the step of forming the inner wall oxide film 3 thereafter, so that the nitrogen concentration has a distribution gradually decreasing from the surface of the inner wall oxide film 3 toward the interface between the inner wall oxide film 3 and silicon substrate 1. Thus, the depth at which nitrogen is introduced in the first step depends little on the final distribution of nitrogen concentration in the inner wall oxide film 3. Therefore, any method such as thermal nitridation, radical nitridation or method using ion species may be employed for the first step.

In contrast, the radical nitridation is used for the second step in order to prevent a great amount of nitrogen from being introduced into the vicinity of the interface between the inner wall oxide film 3 and silicon substrate 1. In this case, nitrogen is introduced into the vicinity of the surface of the inner wall oxide film 3 in the second step. As a result, the distribution of nitrogen concentration in the inner wall oxide film 3 presents a peak in the vicinity of the surface of the trench inner wall.

Accordingly, nitrogen introduced into the inner wall oxide film 3 in the present embodiment diffuses throughout the inner wall oxide film 3 and has a high concentration in the vicinity of the surface of the inner wall oxide film 3. That is, similarly to the first preferred embodiment, nitrogen can be introduced into the inner wall oxide film 3 in a greater amount than in the conventional case, while nitrogen introduced into the vicinity of the interface between the inner wall oxide film 3 and isolation oxide film 4 can be limited to a small amount. Therefore, effects similar to those achieved by the first preferred embodiment can be obtained by the present embodiment.

Further, in the present embodiment, nitrogen introduced in the first step diffuses throughout the inner wall oxide film 3 and does not present a peak in the vicinity of the interface between the inner wall oxide film 3 and silicon substrate 1. Therefore, with respect to control of the problem of thinning of the gate electrode, higher effects than in the first preferred embodiment can be obtained.

As described above, it is preferable to employ the radical nitridation for the second step in the present embodiment, however, the thermal nitridation or method using ion species may be used. This is because, as nitrogen introduced in the first step diffuses throughout the inner wall oxide film 3, the amount of nitrogen required in the second step is smaller than in the conventional method of introducing nitrogen by one step, and because the problem of thinning of the gate electrode at the edges of the active region and the problem of occurrence of a nitrogen-induced level are controlled even when the thermal nitridation is employed, for example, for the second step.

### Third Preferred Embodiment

In the present embodiment, a specific example to which the present invention is applied effectively will be described.

FIG. 8 shows the structure of a semiconductor device according to a third preferred embodiment, illustrating the cross-section of a memory cell region and a peripheral circuit region of a flash memory device. More specifically, the left half illustrates the cross-section of a transistor in the memory cell region (hereinafter referred to as a “memory transistor”) taken along the gate width, and the right half illustrates the cross section of a transistor of a peripheral circuit (hereinafter referred to as a “peripheral transistor”) taken along the gate width.

As shown in FIG. 8, an element isolation structure similar to that described in the first preferred embodiment (see FIGS. 1A and 1B) is formed in the memory cell region and peripheral circuit region of the semiconductor device. More specifically, the isolation oxide film 4 which defines active regions is formed in the trench 2 formed in the silicon substrate 1, and the inner wall oxide film 3 including the first nitride layer 3a and second nitride layer 3b is formed on the inner wall of the trench 2. Hereinafter, the active regions defined by the isolation oxide film 4 in FIG. 8 are referred to as a “first active region” in the memory cell region and a “second active region” in the peripheral circuit region, respectively.

As shown in FIG. 8, the memory transistor is a so-called stacked-gate transistor including a tunnel oxide film 301 (first gate oxide film) formed on the upper surface of the first active region with a floating gate 302 (first gate electrode), an ONO (Oxide-Nitride-Oxide) film 303 and a control gate 304 formed on the tunnel oxide film 301.

The peripheral transistor includes a gate oxide film 401 (second gate oxide film) which is thicker than the tunnel oxide film 301 of the memory transistor and a gate electrode 402 (second gate electrode) formed on the gate oxide film 401. The gate oxide film 401 is formed thicker than the tunnel oxide film 301 in order to achieve a high breakdown voltage.

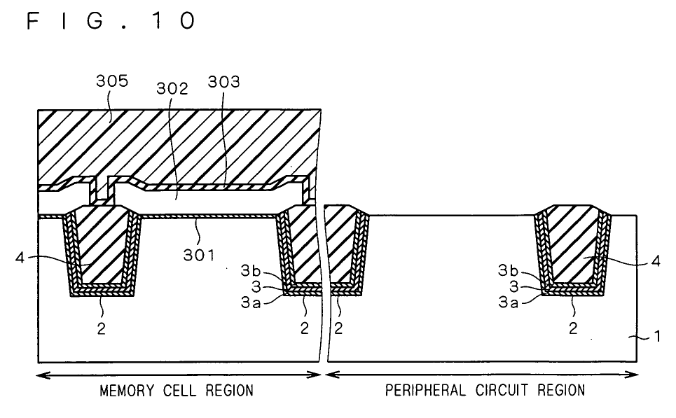

FIGS. 9 and 10 are process drawings showing a method of manufacturing the semiconductor device according to the present embodiment. In these drawings, elements shown in FIG. 8 are indicated by the same reference characters.

First, by the same method employed in the first preferred embodiment, the inner wall oxide film 3 including the first nitride layer 3a and second nitride layer 3b and the isolation oxide film 4 are formed to thereby define the first and second active regions in the memory cell region and peripheral circuit region, respectively.

Then, a silicon oxide film (hereinafter referred to as a “first oxide film”) to form the tunnel oxide film 301 is formed on the entire surface including the upper surfaces of the first and second active regions, and a polysilicon film (hereinafter referred to as a “first conductive film”) to form the floating gate 302 is deposited thereon. Next, the first oxide film and first conductive film located on the first active region are patterned to form the floating gate 302 on the first active region, and the ONO film 303 is formed thereon (FIG. 9). At this stage, as shown in FIG. 9, the first oxide film and first conductive film are not removed by patterning but remain on the second active region in the peripheral circuit region.

Next, a resist 305 is formed to only cover the memory cell region including the first active region, and the first oxide film and first conductive film remaining on the second active region are removed using the resist 305 as a mask (FIG. 10).

Then, after removing the resist 305, a silicon oxide film (hereinafter referred to as a “second oxide film”) to form the gate oxide film 401 of the peripheral transistor is formed on the second active region. The second oxide film is formed thicker than the first oxide film (i.e., the tunnel oxide film 301). Next, for example, a polysilicon film (hereinafter referred to as a “second conductive film”) is formed on the entire surface, and is patterned to form the control gate 304 of the memory transistor and the gate electrode 402 of the peripheral transistor. Thereafter, the source and drain (not shown) are formed in each of the memory transistor and peripheral transistor by a predetermined ion implantation process. The flash memory cell and peripheral circuit having the structure shown in FIG. 8 are thereby obtained.

As described above, by the method of manufacturing the semiconductor device according to the present embodiment, the upper surface of the second active region where the peripheral transistor is to be formed is subjected to two oxidization steps (i.e., the step of forming the first oxide film and the step of forming the second oxide film) after forming the isolation oxide film 4. Also as described above, the gate oxide film 401 made from the second oxide film needs to be formed thicker than the tunnel oxide film 301 (first oxide film) in order to achieve a high breakdown voltage.

More specifically, in the process of manufacturing such semiconductor device, oxidization in the second active region after forming the isolation oxide film 4 is conducted to a great degree. Particularly in this case, it is necessary to sufficiently prevent an oxidizer from reaching the silicon substrate 1 through the isolation oxide film 4 and inner wall oxide film 3. Otherwise, oxidization of the inner wall of the trench 2 positioned around the second active region progresses, causing compressive stress to occur in the second active region, which results in crystal defect, so that the leakage current is increased. The aforementioned conventional method does not fully achieve the effect of preventing an oxidizer from reaching the substrate in the case where oxidization after forming the isolation oxide film is conducted to a great degree.

According to the present invention, as discussed in the first preferred embodiment, the inner wall oxide film 3 includes the first nitride layer 3a and second nitride layer 3b in which nitrogen is introduced in a greater amount than in the conventional case. Therefore, the present invention fully prevents the oxidizer from reaching the silicon substrate 1 even when the second active region is oxidized to a great degree as in the method of manufacturing the semiconductor device according to the present embodiment.

Further, according to the present invention, nitrogen introduced into the vicinity of the interface between the inner wall oxide film 3 and silicon substrate 1 is limited to a small amount. Accordingly, nitrogen remains little at the edges of the first and second active regions on the silicon substrate 1. This can solve the problem of thinning of the tunnel oxide film 301 and gate oxide film 401 at the edges of the active regions, and a nitrogen-induced level is unlikely to occur at the interface between the tunnel oxide film 301 and silicon substrate 1 and that between the gate oxide film 401 and silicon substrate 1. Therefore, the flash memory device is prevented from being degraded in operation reliability. Particularly in the flash memory device, the reliability of the tunnel oxide film 301 is important in electrical characteristics of the device, and thus, the application of the present invention is effective.

The present embodiment has described that the inner wall oxide film 3 and isolation oxide film 4 are formed by a similar method as in the first preferred embodiment, however, it is apparent that the method used in the second preferred embodiment may be employed.

While the invention has been shown and described in detail, the foregoing description is in all aspects illustrative and not restrictive. It is therefore understood that numerous modifications and variations can be devised without departing from the scope of the invention.

1. A method of manufacturing a semiconductor device comprising the steps of:
(a) forming a trench in a semiconductor substrate;
(b) oxidizing an inner wall of said trench to form an inner wall oxide film;
(c) introducing nitrogen into said inner wall oxide film; and
(d) filling said trench with an isolation insulation film, wherein
said step (c) includes the steps of:
(c-1) introducing nitrogen into a relatively deep position in said inner wall oxide film; and
(c-2) introducing nitrogen into a relatively shallow position in said inner wall oxide film.

2. The method according to claim 1, wherein
said step (c-1) is to nitride the vicinity of an interface between said inner wall oxide film and said semiconductor substrate by thermal nitridation using a nitrogen-containing gas, and
said step (c-2) is to nitride said inner wall oxide film by radical nitridation using radial species of nitrogen.

3. The method according to claim 1, further comprising the steps of:
(e) oxidizing the upper surface of a first active region and the upper surface of a second active region, both defined by said isolation insulation film, to form a first silicon insulation film; and
(f) removing part of said first silicon insulation film that is located on said second active region, and thereafter oxidizing the upper surface of said second active region to form a second silicon insulation film.

4. The method according to claim 1, further comprising the steps of:
(e) oxidizing the upper surface of a first active region and the upper surface of a second active region, both defined by said isolation insulation film, to form a first silicon insulation film, and depositing a first conductive film on said first silicon insulation film;
(f) patterning part of said first conductive film that is located on said first active region to form a first gate electrode on said first active region;
(g) forming a resist which covers said first active region after forming said first gate electrode, and removing part of said first silicon insulation film and part of said first conductive film that are located on said second active region using said resist as a mask;
(h) oxidizing the upper surface of said second active region to form a second silicon insulation film, and depositing a second conductive film on said second silicon insulation film; and
(i) patterning said second conductive film on said second active region to form a second gate electrode on said second active region.

5. A method of manufacturing a semiconductor device comprising the steps of:
(a) forming a trench in a semiconductor substrate;
(b) introducing nitrogen into an inner wall of said trench;
(c) oxidizing the inner wall of said trench with nitrogen introduced therein to form an inner wall oxide film;
(d) introducing nitrogen into said inner wall oxide film; and
(e) filling said trench with an isolation insulation film.

6. The method according to claim 5, wherein
said step (b) is to nitride the inner wall of said trench by one of thermal nitridation using a nitrogen-containing gas and radical nitridation using radical species of nitrogen, and
said step (d) is to nitride said inner wall oxide film by radical nitridation using radical species of nitrogen.

7. The method according to claim 5, further comprising the steps of:
(f) oxidizing the upper surface of a first active region and the upper surface of a second active region, both defined by said isolation insulation film, to form a first silicon insulation film; and
(g) removing part of said first silicon insulation film that is located on said second active region, and thereafter oxidizing the upper surface of said second active region to form a second silicon insulation film.

8. The method according to claim 5, further comprising the steps of:
(f) oxidizing the upper surface of a first active region and the upper surface of a second active region, both defined by said isolation insulation film, to form a first silicon insulation film, and depositing a first conductive film on said first silicon insulation film;
(g) patterning part of said first conductive film that is located on said first active region to form a first gate electrode on said first active region;
(h) forming a resist which covers said first active region after forming said first gate electrode, and removing part of said first silicon insulation film and part of said first conductive film that are located on said second active region using said resist as a mask;
(i) oxidizing the upper surface of said second active region to form a second silicon insulation film, and depositing a second conductive film on said second silicon insulation film; and
(j) patterning said second conductive film formed on said second active region to form a second gate electrode on said second active region.

9. A semiconductor device comprising:
a trench formed in a semiconductor substrate;
an inner wall oxide film formed on an inner wall of said trench; and
an isolation insulation film which fills said trench, wherein
nitrogen is contained at least partially in said inner wall oxide film, and
the distribution of concentration of said nitrogen along the thickness of said inner wall oxide film presents two peaks.

10. The semiconductor device according to claim 9, further comprising:
a first active region and a second active region defined by said isolation insulation film in said semiconductor substrate;
a first transistor including a first gate oxide film formed on the upper surface of said first active region; and
a second transistor including a second gate oxide film formed on the upper surface of said second active region, said second gate oxide film having a thickness different from that of said first gate oxide film.

11. A semiconductor device comprising:
a trench formed in a semiconductor substrate;
an inner wall oxide film formed on an inner wall of said trench; and
an isolation insulation film which fills said trench, wherein
nitrogen is contained throughout said inner wall oxide film, and
the distribution of concentration of said nitrogen in said inner wall oxide film presents a peak in the vicinity of a surface of said inner wall oxide film.

12. The semiconductor device according to claim 11, further comprising:
a first active region and a second active region defined by said isolation insulation film in said semiconductor substrate;
a first transistor including a first gate oxide film formed on the upper surface of said first active region; and
a second transistor including a second gate oxide film formed on the upper surface of said second active region, said second gate oxide film having a thickness different from that of said first gate oxide film.

13. A semiconductor device comprising:
a trench formed in a semiconductor substrate;
a first nitride layer formed along an inner wall of said trench;
a second nitride layer formed in an inner side of said trench than said first nitride layer; and
an isolation insulation film which fills said trench.

14. The semiconductor device according to claim 13, further comprising:
a first active region and a second active region defined by said isolation insulation film in said semiconductor substrate;
a first transistor including a first gate oxide film formed on the upper surface of said first active region; and
a second transistor including a second gate oxide film formed on the upper surface of said second active region, said second gate oxide film having a thickness different from that of said first gate oxide film.
